(19) United States
(12) Patent Application Publication
(10) Pub. No.: US 2007/0153943 A1
(43) Pub. Date: Jul. 5, 2007

(54) Turbo equalization scheme

(75) Inventor: Mauri Nissila, Oulu (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/635,634

(22) Filed: Dec. 8, 2006

(30) Foreign Application Priority Data
Dec. 30, 2005 (FI) 20055715

(51) Int. Cl. H03D 1/00; H04B 1/10

(52) U.S. Cl. 375/341; 375/350

(57) ABSTRACT

A flexible solution for turbo equalization is provided. According to the solution, the turbo equalization process is divided into an inner loop equalization process and an outer loop decoding process. Consequently, it is not necessary for each equalization process to be followed by a decoding process. Thus, equalization based soft information on the transmitted data symbols may be updated more frequently than decoding based soft information.

### FIELD

The invention relates generally to signal and information processing techniques in an electronic device, and particularly to joint equalization and decoding of information symbols.

### BACKGROUND

During the past years, turbo coding and turbo equalization have become widely researched areas in telecommunications, because utilization of turbo coding and/or turbo equalization enables data transfer at a rate near the theoretical maximum data transfer rate of a communication channel. The idea behind turbo coding is that data bits to be transmitted are coded with two concatenated codes separated by an interleaver. Decoding of such codes in a receiver is accomplished through an iterative decoding process in which “extrinsic information” is fed back and forth between two decoders. The decoders are separated by an interleaver and a deinterleaver which render the data processed by the first decoder independent of the data processed by the second decoder. Extrinsic information is soft information obtained from the processed data and it may be transferred between the two RSC decoders as log-likelihood ratios (LLR) or probability values. The extrinsic information may describe, for example, the probability of a transmitted encoded bit being either “1” or “−1”. During the iterative process, the probability converges such that the estimate of the transmitted data improves and a reliable hard bit decision can be made.

In turbo equalization, the transmitted data may be protected by a single channel code. Instead of two decoders in a receiver, a SISO (soft input soft output) equalizer is provided in conjunction with a decoder. The SISO equalizer and the decoder are again separated by an interleaver and a deinterleaver. The SISO equalizer improves the extrinsic information by determining the effect of a communication channel on the transmitted data.

The concept of turbo equalization embraces a body of different implementations that provide various tradeoffs between performance and complexity. Various turbo equalizers differ mainly in the structure of the SISO equalizer or in the contents of information exchanged between the SISO equalizer and the decoder. Prior art SISO equalizers may be categorized into two categories: trellis-based (or, equivalently, maximum a posteriori probability, MAP, based) SISO equalizers and soft interference cancellation (SIC) based SISO equalizers. The SIC based SISO equalizers are computationally much simpler than the trellis based ones while the trellis based SISO equalizers usually provide a better performance.

FIG. 1 illustrates a conventional turbo equalizer structure comprising a SIC based SISO equalizer 100. An input to the turbo equalizer consists of encoded data bits (symbols) corrupted by a communication channel. The turbo equalizer comprises a SIC SISO equalizer 100, a symbol demapper 102, a deinterleaver 104, a channel decoder 106, an interleaver 108, a symbol mapper 110 and a conditional mean estimator 112. Let us assume that the received symbols are modulated using QPSK (quadrature phase shift keying) modulation.

The SIC SISO equalizer 100 performs SIC based equalization on the input symbols in order to produce soft output symbols. The equalization is carried out on the basis of knowledge on the state of the communication channel. Each soft output symbol describes a probability that a received symbol is a specific transmitted symbol constellation symbol. Since QPSK modulation was used, the SIC SISO equalizer 100 outputs four soft output symbols for each input symbol, i.e. one probability value for each QPSK symbol constellation symbol.

The soft output symbols are fed to the symbol demapper 102 which produces bit level a posteriori log likelihood ratios (LLR) from the soft symbols received from the SIC SISO equalizer 100. Accordingly, the symbol demapper 102 converts symbol probabilities into bit probabilities which are presented as LLRs. Since QPSK modulation was used, each symbol represents two bits, and the symbol demapper 102 outputs two LLRs for each input symbol. In practice, the symbol demapper 102 converts the four probability values into two LLRs. These LLRs are used as a priori information in the channel decoder 106. Before feeding the LLRs to the channel decoder 106, the LLRs are deinterleaved in the deinterleaver 104 in order to remove the correlation between different LLRs of the received symbols. A common implementation of the channel decoder 106 is a Maximum a posteriori probability (MAP) based decoder which uses a max-log-MAP algorithm. The channel decoder calculates and outputs soft likelihood values (LLRs) for transmitted bits, and these values are fed to the symbol mapper 110 through the interleaver 108. The symbol mapper 110 calculates soft symbol values from the bit level a priori likelihood values (LLRS) provided by the channel decoder 106. Accordingly, the symbol mapper 110 converts the bit probabilities in the form of LLRs into symbol probabilities. The symbol probabilities are converted into a soft symbol value in a symbol converter 112. The symbol converter 112 may employ conditional mean estimation when calculating soft symbol values. The soft symbol values are fed to the SIC SISO equalizer 100 which again utilizes a known channel state in providing better soft estimates on the soft symbols provided by the symbol converter 112. The above described process is repeated a determined number of times and, during the iterative process, the soft symbol estimates improve. After the iterative process has been carried out a determined number of times, the channel decoder 106 may output hard bit decisions of the transmitted bits.

The messages from the SISO equalizer 100 to the channel decoder 106 should always be in the form of extrinsic information whereas the messages from the channel decoder 106 to the SISO equalizer 100 may be either in the form of extrinsic information or in the form of full information. Full information denotes a combination of the output of the channel decoder 106 and the output of the equalizer 100 in the previous iteration. The trellis-based equalizers should be provided with extrinsic information while the SIC based equalizers should be provided with full information.

### BRIEF DESCRIPTION OF THE INVENTION

An object of the invention is to provide an improved solution for combined equalization and decoding in an electronic device.

According to a first aspect of the invention, there is provided a combined equalization and decoding method in an electronic device, the method being divided into an inner loop equalization process and an outer loop decoding process, the method comprising: receiving information transmitted through a communication channel; carrying out the inner loop equalization process in order to produce a first soft estimate of the transmitted information by applying known information on properties of the communication channel to the received information; carrying out the outer loop decoding process in order to produce a second soft estimate of the transmitted information by applying channel code information to the first soft estimate of the transmitted information; feeding the second soft estimate of the transmitted information back to the equalizer for production of an additional soft estimate of the transmitted information; carrying out inner loop equalization and outer loop decoding processes for respectively determined number of times, the total number of inner loop equalization processes being determined to be higher than the total number of outer loop decoding processes, and outputting decoded information after the outer loop decoding process has been carried out for the last time.

According to a second aspect of the invention, there is provided a combined equalization and decoding method in an electronic device, the method being divided into an inner loop equalization process and an outer loop decoding process, the method comprising: receiving information transmitted through a communication channel; carrying out the inner loop equalization process in order to produce a first soft estimate of the transmitted information by applying known information on properties of the communication channel to the received information; determining, after each inner loop equalization process, on the basis of a result of the inner loop equalization process, whether or not to carry out an additional inner loop equalization process in order to improve the first soft estimate; carrying out the additional inner loop equalization process by applying known information on the properties of the communication channel to the soft estimate obtained in a previous inner loop equalization process, if it has been determined that the additional inner loop equalization process is to be carried out; carrying out the outer loop decoding process in order to produce a second soft estimate of the transmitted information by applying channel code information to the first soft estimate of the transmitted information obtained as a result of the latest inner loop equalization process if it has been determined that no additional inner loop equalization process is to be carried out; feeding the second soft estimate of the transmitted information back to the equalizer for production of an additional soft estimate of the transmitted information; carrying out inner loop equalization and outer loop decoding processes for respectively determined number of times, and outputting decoded information after the outer loop decoding process has been carried out for the last time.

According to a third aspect of the invention, there is provided an electronic device comprising: a reception unit configured to receive information transmitted through a communication channel; an equalization unit configured to equalize the received information, produce a first soft estimate of the transmitted information by applying known information on properties of the communication channel to the received information, and output the first soft estimate of the transmitted information; a decoding unit configured to produce a second soft estimate of the transmitted information by applying channel code information to the first soft estimate of the transmitted information received from the equalization unit, and feed the second soft estimate of the transmitted information back to the equalization unit for production of an additional soft estimate of the transmitted information, or output decoded information after the decoding unit has decoded the first soft estimate of the transmitted information for the last time, the electronic device further comprising a controller configured to control processing of received information by determining, respectively, the number of times the equalization unit equalizes the received information and the number of times the decoding unit decodes the first soft estimate received from the equalization unit, the total number of equalization processes being determined to be higher than the total number of decoding processes.

According to a fourth aspect of the invention, there is provided an electronic device comprising: a reception unit configured to receive information transmitted through a communication channel; an equalization unit configured to equalize the received information, produce a first soft estimate of the transmitted information by applying known information on properties of the communication channel to the received information, and output the first soft estimate of the transmitted information; a decoding unit configured to produce a second soft estimate of the transmitted information by applying channel code information to the first soft estimate of the transmitted information received from the equalization unit, and feed the second soft estimate of the transmitted information back to the equalization unit for production of an additional soft estimate of the transmitted information or output the decoded information after the decoding unit has decoded the first soft estimate of the transmitted information for the last time, the electronic device further comprising a controller configured to determine, after each equalization process carried out by the equalization unit, on the basis of a result of the equalization process, whether or not to carry out an additional equalization process in order to improve the first soft estimate before decoding process, and feed the first soft estimate of the transmitted information back to the equalization unit for the additional equalization if the controller determines that another equalization process is to be carried out, or to the decoding unit for the decoding, if the controller determines that no other equalization process is to be carried out before the decoding process.

According to a fifth aspect of the invention, there is provided an electronic device comprising: reception means for receiving information transmitted through a communication channel; equalization means for equalizing the received information, producing a first soft estimate of the transmitted information by applying known information on properties of the communication channel to the received information, and outputting the first soft estimate of the transmitted information; decoding means for producing a second soft estimate of the transmitted information by applying channel code information to the first soft estimate of the transmitted information received from the equalization unit, and feeding the second soft estimate of the transmitted information back to the equalization unit for production of an additional soft estimate of the transmitted information, or outputting decoded information after the decoding means have decoded the first soft estimate of the transmitted information for the last time, the electronic device further comprising means for controlling processing of received information by determining, respectively, the number of times the equalization means equalize the received information and the number of times the decoding means decode the first soft estimate received from the equalization means, the total number of equalization processes being determined to be higher than the total number of decoding processes.

According to a sixth aspect of the invention, there is provided an electronic device comprising: reception means for receiving information transmitted through a communication channel; equalization means for equalizing the received information, producing a first soft estimate of the transmitted information by applying known information on properties of the communication channel to the received information, and outputting the first soft estimate of the transmitted information; decoding means for producing a second soft estimate of the transmitted information by applying channel code information to the first soft estimate of the transmitted information received from the equalization unit, feeding the second soft estimate of the transmitted information back to the equalization means for production of an additional soft estimate of the transmitted information or outputting decoded information after the decoding means have decoded the first soft estimate of the transmitted information for the last time, the electronic device further comprising means for determining, after each equalization process carried out by the equalization means, on the basis of a result of the equalization process, whether or not to carry out an additional equalization process in order to improve the first soft estimate before decoding process, and feed the first soft estimate of the transmitted information back to the equalization means for the additional equalization if it is determined that another equalization process is to be carried out, or to the decoding means for the decoding, if it is determined that no other equalization process is to be carried out before the decoding process.

According to a seventh aspect of the invention, there is provided a computer program product encoding a computer program of instructions for executing a computer process for combined equalization and decoding in an electronic device, the process comprising: receiving information transmitted through a communication channel; carrying out the inner loop equalization process in order to produce a first soft estimate of the transmitted information by applying known information on properties of the communication channel to the received information; carrying out the outer loop decoding process in order to produce a second soft estimate of the transmitted information by applying channel code information to the first soft estimate of the transmitted information; feeding the second soft estimate of the transmitted information back to an equalizer for production of an additional soft estimate of the transmitted information; carrying out inner loop equalization and outer loop decoding processes for respectively determined number of times, the total number of inner loop equalization processes being determined to be higher than the total number of outer loop decoding processes, and outputting decoded information after the outer loop decoding process has been carried out for the last time.

According to an eighth aspect of the invention, there is provided a computer program distribution medium readable by a computer and encoding a computer program of instructions for executing a computer process for combined equalization and decoding in an electronic device, the process comprising: receiving information transmitted through a communication channel; carrying out an inner loop equalization process in order to produce a first soft estimate of the transmitted information by applying known information on properties of the communication channel to the received information; carrying out an outer loop decoding process in order to produce a second soft estimate of the transmitted information by applying channel code information to the first soft estimate of the transmitted information; feeding the second soft estimate of the transmitted information back to equalizer for production of an additional soft estimate of the transmitted information; carrying out inner loop equalization and outer loop decoding processes for respectively determined number of times, the total number of inner loop equalization processes being determined to be higher than the total number of outer loop decoding processes, and outputting decoded information after the outer loop decoding process has been carried out for the last time.

According to a ninth aspect of the invention, there is provided a computer program product encoding a computer program of instructions for executing a computer process for combined equalization and decoding in an electronic device, the process comprising: receiving information transmitted through a communication channel; carrying out the inner loop equalization process in order to produce a first soft estimate of the transmitted information by applying known information on properties of the communication channel to the received information; determining, after each inner loop equalization process, on the basis of a result of the inner loop equalization process, whether or not to carry out an additional inner loop equalization process in order to improve the first soft estimate; carrying out the additional inner loop equalization process by applying known information on the properties of the communication channel to the soft estimate obtained in the previous inner loop equalization process, if it has been determined that the additional inner loop equalization process is to be carried out; carrying out the outer loop decoding process in order to produce a second soft estimate of the transmitted information by applying channel code information to the first soft estimate of the transmitted information obtained as a result of the latest inner loop equalization process if it has been determined that the no additional inner loop equalization process is to be carried out; feeding the second soft estimate of the transmitted information back to the equalizer for production of an additional soft estimate of the transmitted information; carrying out inner loop equalization and outer loop decoding processes for respectively determined number of times, and outputting decoded information after the outer loop decoding process has been carried out for the last time.

According to another aspect of the invention, there is provided a computer program distribution medium readable by a computer and encoding a computer program of instructions for executing a computer process for combined equalization and decoding in an electronic device, the process comprising: receiving information transmitted through a communication channel; carrying out the inner loop equalization process in order to produce a first soft estimate of the transmitted information by applying known information on properties of the communication channel to the received information; determining, after each inner loop equalization process, on the basis of the result of the inner loop equalization process, whether or not to carry out an additional inner loop equalization process in order to improve the first soft estimate; carrying out the additional inner loop equalization process by applying known information on the properties of the communication channel to the soft estimate obtained in the previous inner loop equalization process, if it has been determined that the additional inner loop equalization process is to be carried out; carrying out the outer loop decoding process in order to produce a second soft estimate of the transmitted information by applying a channel code information to the first soft estimate of the transmitted information obtained as a result of the latest inner loop equalization process, if it has been determined that the additional inner loop equalization process shall not be carried out; feeding the second soft estimate of the transmitted information back to the equalizer for production of an additional soft estimate of the transmitted information; carrying out inner loop equalization and outer loop decoding processes for respectively determined number of times, and outputting decoded information after the outer loop decoding process has been carried out for the last time.

The invention provides several advantages. The invention provides a flexible arrangement and scheduling of messages passing between an equalizer and a decoder by introducing a double loop message-passing scheme. Another advantage of this arrangement is that significant computational savings can be achieved by circulating messages within an inner equalization loop more frequently than in an outer decoding loop. Decoding is clearly the more complex process, and recently it has been observed that it is advantageous to update the information obtained through the equalization process more frequently.

### LIST OF DRAWINGS

In the following, the invention will be described in greater detail with reference to embodiments and the accompanying drawings, in which

FIG. 1 shows a conventional turbo equalization principle;

FIG. 2 illustrates an electronic device according to an embodiment of the invention;

FIG. 3 illustrates a turbo equalizer according to an embodiment of the invention;

FIG. 4A illustrates a soft symbol value of a received symbol with respect to symbols of a symbol constellation during a combined equalization and decoding process according to an embodiment of the invention;

FIG. 4B illustrates a soft symbol value of a received symbol with respect to the symbols of a symbol constellation during a combined equalization and decoding process according to an embodiment of the invention;

FIG. 4C illustrates a soft symbol value of a received symbol with respect to symbols of a symbol constellation during a combined equalization and decoding process according to an embodiment of the invention;

FIG. 4D illustrates a soft symbol value of a received symbol with respect to symbols of a symbol constellation during a combined equalization and decoding process according to an embodiment of the invention;

FIG. 5 illustrates a turbo equalizer according to another embodiment of the invention, and

FIG. 6 is a flow chart illustrating a process for combined equalization and decoding according to an embodiment of the invention.

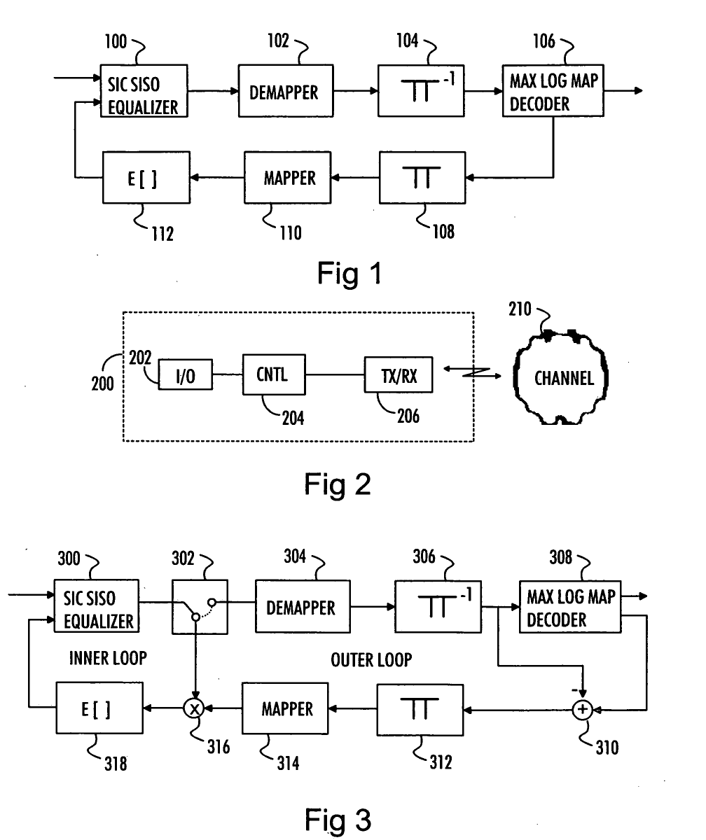

### DESCRIPTION OF EMBODIMENTS

With reference to FIG. 2, examine an example of the structure of an electronic device 200 to which embodiments of the invention can be applied. The electronic device 200 in FIG. 2 is a communication device 200 capable of wireless and/or wired communications and capable of at least receiving information transmitted through a communication channel 210. The communication device 200 may be capable of receiving information transmitted according to at least one of the following techniques: GPRS (General Packet Radio Service), EDGE (Enhanced Data Rates for GSM evolution), WCDMA (Wideband Code Division Multiple Access), xDSL (Digital Subscriber Line), WLAN (Wireless Local Area Network). The communication device 200 is not, however, limited to these techniques, and the invention may be applied to other environments in which turbo equalization is utilized. The communication device 200 may, for example, be a personal communication or information-processing device, such as a computer, a PDA (Personal Digital Assistant), a mobile phone. The communication device 200 may also be an element of a communication network, such as a base station of a mobile communication system or an access point to a WLAN. The communication device 200 may also be a device configured to convert data from one transport format to another, such as an xDSL modem.

The communication device 200 comprises a communication interface 206 for receiving information transmitted through the communication channel 210. The communication interface 206 may be a reception unit configured to receive information transmitted by using any communication technique stated above. The communication interface 206 may be configured to process received information signals to a certain degree. The communication interface 206 may be configured to filter and amplify the received information signals as well as to convert the analog information signals into a digital form. In addition to receiving information signals, the communication interface 206 may be configured to transmit information signals through the communication channel 210.

The communication device 200 further comprises a processing unit 204 configured control operations of the communication device 200. The processing unit 204 may be configured to process information received through the communication interface 206. In particular, the processing unit 204 may be configured to perform digital signal processing algorithms on the received information in order to reliably detect the received information. The processing unit 204 may apply, for example, turbo equalization principles to the received information. The processing unit 204 may be implemented with a digital signal processor provided with suitable software embedded on a computer readable medium, or with separate logic circuits, for example with ASIC (Application Specific Integrated Circuit).

The communication device 200 may further comprise an input/output (I/O) unit 202 for inputting and/or outputting information to/from the communication device 200. The I/O unit 202 may comprise means for transmitting information received through the communication interface 206 and processed by the processing unit 204 by using a specific transmission technique. For example, if the communication device 200 is a base station, the communication interface receives information transmitted through a radio channel, and the I/O device may further transmit the corresponding information to a base station controller through a wired connection.

The communication device 200 may also comprise a user interface for interaction with a user of the communication device, and other components which will not be described in detail herein.

Instead of being the communication device, the electronic device according to an embodiment of the invention may be any other electronic device configured to process encoded information according to an embodiment of the invention.

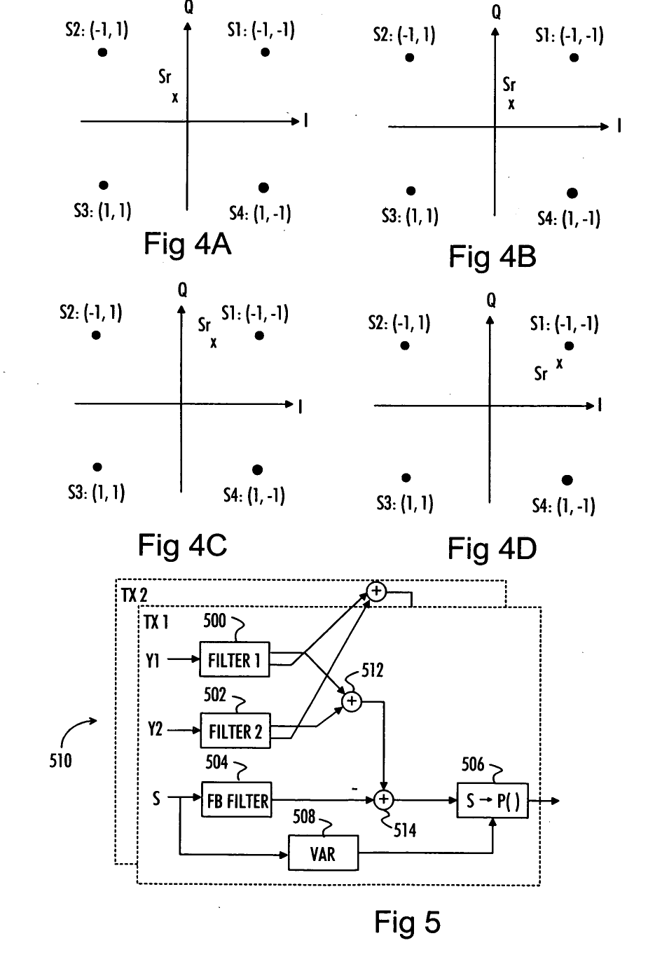

Next, turbo equalization according to an embodiment of the invention will be described with reference to FIG. 3 and FIGS. 4A to 4D. Referring to FIG. 3, a received signal is received through a reception unit (e.g. the communication interface 206) which converts the received signal into a plurality of received symbols. Let us assume that the received symbols have been modulated by using a QPSK modulation scheme in a transmitter. The received symbols are usually corrupted in a communication channel with interference which may be inter symbol interference, multiple access interference, or inter system interference caused by other communication systems operating on the same frequency band. The turbo equalizer of FIG. 3 attempts to process the received symbols in order to recover the transmitted symbols through iterative equalization and decoding processes.

A block of received symbols is inputted to an equalization unit 300. The received symbols comprise the transmitted symbols, interference, and thermal noise. The equalization unit 300 may be a soft interference cancellation based equalizer which estimates the interference in the received symbols and filters the interference from the received symbols. The result of the filtering comprises the transmitted symbols, some residual interference the equalizer was not able to remove, and thermal noise. The equalization unit 300 may be configured to estimate one or several of the following interference types: inter symbol interference, multiple access interference, and inter system interference. The equalization unit 300 may also be configured to estimate other types of interference.

After the filtering, the equalization unit 300 may calculate a soft estimate of each transmitted symbol. The soft estimate of a transmitted symbol comprises probability values for each possibly transmitted symbol. Now that QPSK modulation was used, the soft estimate of the transmitted symbol comprises four probabilities, each probability being associated with different QPSK constellation symbol. Referring to FIG. 4a, which illustrates a QPSK symbol constellation S1, S2, S3, and S4, a received symbol may have a soft symbol value Sr after the first filtering. A soft estimate for the received symbol may be derived by first calculating an Euclidean distance between the soft symbol value Sr and each symbol constellation symbol S1, S2, S3, and S4. Then, by applying the calculated Euclidean distances and calculated variance of the estimated interference, four probability values are obtained, each probability value describing a probability that the received symbol is a given symbol constellation symbol. According to the example in FIG. 4a, the probability that the received symbol is S2 is a slightly higher than probabilities for other symbols. Each received symbol is processed in the same way. Then, the equalization unit 300 may output the soft estimate of the transmitted information, i.e. the four probability values for each received symbol.

From the equalization unit 300, the soft estimate of the transmitted information is fed to a switch 302 which divides the turbo equalization process to an inner loop equalization process and an outer loop decoding process. The switch 302 may be controlled by a controller (not shown) which determines whether the output of the equalization unit 300 is forwarded for other inner loop equalization or for outer loop decoding. The controller may operate according to several criteria as will be described below.

Let us assume that a controller instructs the switch 302 to forward the output of an equalization unit for another equalization process. Accordingly, the switch 302 connects the output of the equalization unit 300 to an input of a multiplier 316. The multiplier 316 multiplies the output of the equalization unit 300 with the output of a symbol mapper 314 whose output comprises soft estimates of the transmitted symbols obtained as the result of an outer loop decoding process, which will be described below. Thus, the multiplier 316 combines the result of the inner loop equalization process with the result of the outer loop decoding process. Actually, the multiplier 316 combines (multiplies) the probability values of each symbol output received from the equalization unit 300 with the corresponding probability values outputted from the decoding process. Now that no outer loop decoding process has yet been carried out, the input to the multiplier 316 from the symbol mapper 314 consists only ones, which means that the input from the equalization unit 300 is forwarded to the output of the multiplier 316. The multiplier 316 outputs the combined soft estimates of the transmitted information (the combined probability values) to a symbol converter 318.

The symbol converter 318 converts the received probability values into soft symbol values. In our example with QPSK modulation, the symbol converter 318 calculates a soft symbol value from the four probability values associated with one received symbol. The symbol converter 318 may calculate an expected value for the soft symbol from the probability values. Thus, the symbol converter 318 converts the four probability values, each being associated with S1, S2, S3, or S4 in FIG. 4A, to the soft symbol value Sr in FIG. 4A. The symbol Sr is then outputted to the equalization unit 300 for another equalization process. The same procedure is carried out for the probability values associated with each received symbol of the processed block of received symbols.

Upon reception of the soft symbol values from the symbol converter 318, the equalization unit 300 carries out another soft interference cancellation based equalization on the received symbol values. The equalization unit 300 may estimate residual interference in the soft symbols and filter the estimated residual interference from the soft symbols. Then, the equalization unit 300 may calculate new soft estimates of the transmitted symbols, i.e. the new probability values for each received symbol. The calculation may again comprise calculation of Euclidean distances between a newly equalized received soft symbol Sr in FIG. 4B with each symbol constellation point S1, S2, S3, and S4 in FIG. 4B, and calculation of the variance of the residual interference. Again, four probability values are obtained for each received soft symbol value, and these probability values are outputted from the equalization unit 300. As can be seen, when comparing a first equalized received symbol Sr in FIG. 4A with a newly equalized, corresponding soft symbol Sr in FIG. 4B, the additional equalization has changed the soft symbol value such that the most probable transmitted symbol is now S1 (−1, −1).

The output of the equalization unit 300 is again fed to the switch 302 controlled by a controller (not shown), and the switch 302 again connects, according to instructions received from the controller, the output either to the input of the multiplier 316 or to the input of a symbol demapper 304. Let us now assume that the controller instructs the switch 302 to forward the output of the equalization unit 300 to the input of the symbol demapper 304.

The symbol demapper 304 converts the symbol level soft estimates of the transmitted symbols into bit level soft estimates of the transmitted symbols (or bits). The symbol demapper 304 may convert each probability value received from the equalization unit 300 through the switch 302 into a plurality of log-likelihood ratio values. The number of log-likelihood ratio values obtained from one probability value depends on the symbol constellation used for modulating the transmitted symbols. In our example with QPSK modulation, each symbol constellation symbol represents two bits (for example symbol S2 in FIGS. 4A to 4D represents transmitted bits −1 and 1). Therefore, the symbol demapper 304 produces two log-likelihood ratio values for each symbol constellation symbol, i.e. the number of log-likelihood ratio values is twice the number of received symbols.

As mentioned above, each received QPSK symbol represents two bits. When calculating a log-likelihood ratio for the first bit, the received probability values (soft estimates of the transmitted symbol) associated with a received symbol and calculated in the equalization unit 300 may be used as will be described next. The probability values which indicate that the first bit is 1 (probability values associated with symbols S3 and S4 in FIG. 4A to 4D) are summed together. Similarly, the probability values which indicate that the first bit is −1 (probability values associated with symbols S1 and S2 in FIG. 4A to 4D) are summed together. Then, a logarithm (In) may be calculated from the both results of the summations, and the logarithm associated with the summed probabilities of symbols S1 and S1 may be subtracted from the logarithm associated with the summed probabilities of symbols S3 and S4. A similar procedure is carried out for the second bit of the received QPSK symbol. Now, probabilities associated with symbols S1 and S4 (indicating that the second bit is −1) are summed together. Similarly, probabilities associated with symbols S2 and S3 (indicating that the second bit is 1) are summed together. The symbol demapper 304 then outputs log-likelihood ratios for each bit in the received symbols.

The output of the symbol demapper 304 is fed to a deinterleaver 306. At this stage, it should be noticed that the transmitted data bits have been interleaved in a transmitter, and the deinterleaver 306 rearranges the data interleaved by the interleaver in the transmitter. The deinterleaver 306 may be a block-type deinterleaver which deinterleaves the block of processed data (the log-likelihood ratios) and ouputs the deinterleaved block of data (the log-likelihood ratios).

The output of the deinterleaver 306 is fed to a decoding unit 308 and to a subtracting unit (an adder 310). The decoding unit 308 may be a “max log MAP (maximum a posteriori probability)” based decoder which processes the input log-likelihood ratios with the pre-knowledge of the channel code used for encoding the transmitted bits in the transmitter. By applying the channel code information to the log-likelihood ratio values, the decoding unit 308 improves the soft estimate of the transmitted bits. The decoding unit 308 outputs log-likelihood ratios which have been updated on the basis of the channel coding information. The decoding unit 308 may be a state-of-the-art max log MAP decoder.

The output of the decoding unit now comprises log-likelihood ratios of transmitted bits, the log-likelihood ratios including soft information provided by the equalization unit 300 and soft information provided by the decoding unit 308. It should be reminded herein that the multiplier 316 combines the output of the inner loop equalization process (soft information provided by the equalization unit) and the output of the outer loop decoding process (soft information provided by the decoding unit 308). Now that the output of the decoding unit 308 already includes the soft information provided by the equalization unit 300, this soft information should be removed from the output of the decoding unit before the multiplier in order not to include the soft information provided by the equalization unit 300 twice. The removal may be carried out in the subtracting unit (the adder 310) which subtracts the log-likelihood ratios at the output of the deinterleaver 306 from the log-likelihood ratios at the output of the decoding unit 308. The output of the adder 310 then consists of the additional soft information obtained in the decoding process carried out by the decoding unit 308. At this stage, it should be noticed that the multiplication in the multiplier 316 is compensated by a subtraction in the adder 310 because the values inputted to the adder are logarithmic.

The output of the adder 310 is fed to an interleaver 312 which interleaves the input log-likelihood ratios. The interleaver 312 may be a block-type interleaver of the same size as the deinterleaver 306, and the interleaver rearranges the input log-likelihood ratios in the same order as they were before the deinterleaver 306. One function of the deinterleaver 306 and the interleaver 312 is to keep the soft information provided by the equalization unit 300 and the decoding unit 308 mutually uncorrelated, thus enabling the soft estimates of the transmitted data to be improved over the iterative turbo equalization process.

The output of the interleaver 312 is fed to the symbol mapper 314 which converts the bit level log-likelihood values to symbol level probability values. The symbol mapper 314 may first calculate bit probability values for each log-likelihood ratio, i.e. calculate a probability for that the bit associated with the log-likelihood ratio value being 1 and a probability for that the bit associated with the log-likelihood ratio value being −1. Then, the symbol mapper 314 may combine (multiply) the bit probability values into symbol probability values according to the symbol constellation used for modulating the bits (in our example QPSK symbol constellation). For example, when calculating a probability value for symbol S1 in FIGS. 4A to 4D, the bit probability value indicating that the first bit is −1 and the bit probability value indicating that the second bit is −1 are multiplied together. In our example, the output of the symbol mapper 314 with QPSK symbol constellation comprises four symbol probability values, one for each symbol constellation symbol S1, S2, S3, and S4, from two input bit level log-likelihood ratios.

The output of the symbol mapper 314 is fed to the multiplier 316 which multiplies the probability values outputted from the symbol mapper 314 with the corresponding probability values outputted from the equalization unit 300 after the most recent inner loop equalization process. Then, the symbol converter 318 converts the probability values into soft symbol values and feeds the soft symbol values to the equalization unit 300 for another equalization. At the input to the equalization unit 300, a soft symbol Sr in FIGS. 4A to 4D may have a value as illustrated in FIG. 4C which indicates another change in the value towards the symbol S1. The change from the value in FIG. 4B represents improvement in the soft estimate of the transmitted symbol obtained through the outer loop decoding process. After the additional equalization carried out in the equalization unit 300, the soft symbol Sr may have a value as illustrated in FIG. 4D which now indicates an even higher probability that the transmitted symbol is indeed S1.

In contrast to the example of FIGS. 4A to 4D, a corresponding improvement of the soft estimate of the transmitted symbol may require several iterations in both the inner loop equalization process and the outer loop decoding process. When a determined number of inner loop equalization and outer loop decoding processes has been carried out, hard bit decisions are made in the decoding unit 308, and the bit decisions are outputted from the decoding unit for further processing. The decoding unit 308 may comprise logic which instructs the decoding unit 308 either to output log-likelihood values for another turbo equalization process or to make bit decisions and output the bit decisions for further processing.

It should be noticed that various alternatives exist for implementing the inner loop and the outer loop in the turbo equalizer according to an embodiment of the invention. In FIG. 3, the inner loop comprises the equalization unit 300, the switch 302, the mulitplier 316, and the symbol converter 318. In another implementation, the inner loop may comprise the equalization unit 300, the switch 302, the symbol mapper 304, and the symbol demapper. In this implementation, the switch 302 would be located between the symbol demapper 304 and the deinterleaver 306, and the multiplier would be replaced by an adder which would be located between the symbol mapper 314 and the interleaver 312. The adder would have inputs from the symbol demapper 314 (through the switch 302) and from the interleaver. An advantage in this implementation would be that multiplication in the multiplier 316 would be replaced by a summation in the adder, since the summed soft information would comprises logarithmic values. In some environments, this implementation may be advantageous. Generally, the design of the inner loop and the outer loop is only a matter of implementation of the turbo equalization principle according to an embodiment of the invention.

As discussed above, the switch 302 divides the turbo equalization process into the inner loop equalization process and the outer loop decoding process. The advantage is that the turbo equalization is not limited to an equalization process being compelled to be followed by a decoding process. The decoding process is significantly more complex than the equalization process, and recently it has been observed that it would be advantageous to update the soft estimates produced by the equalization process more frequently than the soft estimates produced by the decoding process.

The decision of whether to update the soft estimates produced by the equalization unit 300 with another equalization or to move to the decoding process is made by the controller (not shown) controlling the switch 302 in FIG. 3. The controller may make the decision on the basis of various criteria. Accordingly, the controller may determine the number of inner loop equalization process and the number of outer loop decoding process respectively. The controller may determine that a given number of inner loop equalization processes must be carried out before each outer loop decoding process, and the total number of inner loop equalization processes is higher than the total number of the outer loop decoding processes in the turbo equalization process according to an embodiment of the invention. The number of inner loop equalization processes before each outer loop decoding process may be predetermined. The controller may, for example, determine that two inner loop equalization processes are carried out before each outer loop decoding process. The controller may also determine that the number of consecutive inner loop equalization processes before each outer loop decoding process varies during the turbo equalization process according to an embodiment of the invention.

Instead of a predetermined order of the inner loop equalization and outer loop decoding processes, the controller may adaptively determine after each equalization process whether to carry out another inner loop equalization process or to carry out the outer loop decoding process. The decision may, for example, be based on the result of the most recent equalization process. The controller may, for example, calculate the residual interference variance in the result of the equalization process and determine, on the basis the calculated interference variance or the change in the interference variance, whether another inner loop equalization process should be carried out. The controller may compare the calculated variance with a threshold value, and if the calculated variance is higher than the threshold, the controller may decide for another equalization process. Alternatively, the controller may monitor the improvement in the calculated interference variance between the most recent and the previous equalization process. For example, if some considerable improvement has been achieved in the residual interference variance, i.e. the variance has reduced considerably, the controller may decide for another equalization process. On the other hand, if only some marginal improvement in the residual interference variance was achieved, the controller may decide that a decoding process should be carried out. The controller may again compare the improvement in the residual interference with a threshold value and base the decision on that.

FIG. 5 illustrates a structure of an equalization unit 510 implemented in a communication device according to an embodiment of the invention. The equalization unit 510 is adapted to process signals received through a plurality of receiver antennas. The signals received in the antennas of the communication device may be transmitted by implementing a “MIMO” (Multiple Input Multiple Output) communication scheme in which a transmitter has a plurality of transmit antennas and it transmits independent information from each of the plurality of transmit antennas, thus providing either diversity gain or higher data rates. Let us assume that the transmitter also has two antennas. The equalization unit 510 receives signals through two antennas and radio front-end components following the antennas and converting the radio signals into information symbols. The symbols received through the first and the second antenna are denoted with Y1 and Y2, respectively.

The received symbols Y1 are fed to a first filter 500 which equalizes the symbols Y1 by estimating interference in the symbols Y1 and filtering the symbols Y1. The first filter 500 is also capable of separating the symbols transmitted from the first transmit antenna and the symbols transmitted from the second transmit antenna. The first filter 500 has two outputs, one for the symbols transmitted from the first transmit antenna and one for the symbols transmitted from the second transmit antenna. The operation of the second filter 502 is similar to that of the first filter 500 but the second filter 502 has symbols Y2 as input symbols. The symbols transmitted from the first transmit antenna are combined in an adder 512, and fed to another adder 514. The adder 514 subtracts estimated residual interference produced in a feedback filter 504 from the combined symbols input from the adder 512. In the first equalization process, there are no soft symbol values available in the feedback filter 504 for the calculation of the residual interference and, therefore, the residual interference is zero. From the adder 514, the symbols are fed to a soft estimate production unit 506 which produces probability values for each symbol constellation symbol from each received symbol. The procedure may be the same as described above with respect to FIG. 3 and the equalization unit 300. The probability values may be calculated by taking into account residual interference variance estimated in an interference variance estimation unit 508. The soft estimate production unit 506 may then output the probability values to, for example, a switch controlled by a controller which determines whether to connect the output of the soft estimate production unit to the multiplier 316 for another inner loop equalization process or to the symbol demapper 304 for an outer loop decoding process. The same procedure is carried out in parallel to the symbols transmitted from the second transmit antenna of the transmitter.

In the next inner loop equalization process, input soft symbol values are fed to the feedback filter 504 and to the interference variance estimation unit 508. The feedback filter updates the residual interference estimate and the updated interference estimate is subtracted from the combined symbols in the adder 514.

The equalization may be carried out in a time domain or in a frequency domain. In some situations one may be more suitable than the other. For example, if the impulse response of a radio channel has a long delay spread, the frequency domain equalization is more suitable from the point of view of complexity because the length of a time domain equalization filter would be longer.

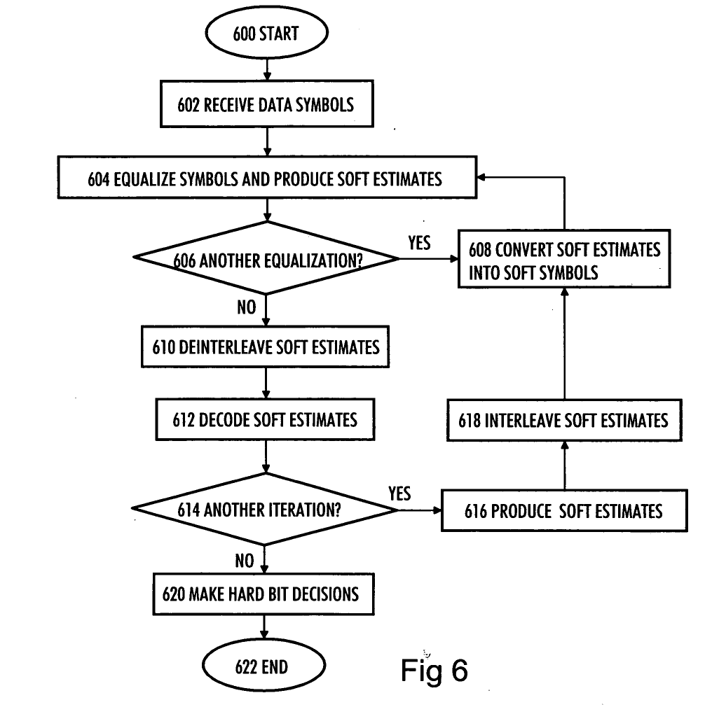

Next, a turbo equalization process according to an embodiment of the invention will be described with reference to the flow diagram in FIG. 6. The process starts in block 600.

In block 602, a block of data symbols is received. The received data symbols are equalized and first soft estimates of the transmitted data symbols are produced from the equalized data symbols in block 604. In block 606, it is determined whether or not to carry out another equalization process. If it is determined that another equalization process is to be carried out, the process moves to block 608 in which the first soft estimates of the transmitted symbols are converted into soft symbol values. The process then moves to block 604 in which the converted soft symbol values are equalized again and improved first soft estimates of the transmitted symbols are produced.

If it is determined in block 606 that no other equalization process is be carried out, the process moves to block 610 in which the first soft estimates are deinterleaved. Prior to deinterleaving, the first soft estimates may be converted into log-likelihood ratios (not shown).

From block 610, the process moves to block 612 in which the first soft estimates of the transmitted information are decoded by applying knowledge on the channel code used for encoding the transmitted symbols in a transmitter to the first soft estimates (log-likelihood ratios).

In block 614, it is determined whether or not to carry out another turbo equalization iteration. If it is determined that another iteration is to be carried out, the process moves to block 616 in which second soft estimates of the transmitted symbols are produced. The second soft estimates are improved with respect to the first soft estimates since the channel code information was applied to the first soft estimates. From block 616, the process moves to block 618 in which the second soft estimates are interleaved. The process moves then to block 608.

It should be noted that in block 608 the first soft estimates of the transmitted symbols may be combined with the second soft estimates of the transmitted symbols. Consequently, the effect of the first soft symbols may be removed after the decoding process carried out in block 612. This removal may be carried out, for example, in block 616 in order not to include the first soft estimates twice in the combination procedure.

If it is determined in block 614 that no other iteration is to be carried out, the process moves to block 620 in which hard bit decisions are made from the decoded first soft estimates of the transmitted information. The process ends in block 622.

The embodiments of the invention may be realized in an electronic device comprising a processing unit 204. The processing unit 204 may be configured to perform at least some of the steps described in connection with the flowchart of FIG. 6 and in connection with FIGS. 3 and 5. The embodiments may be implemented as a computer program comprising instructions for executing a computer process for iterative equalization and decoding in the electronic device.

The computer program may be stored on a computer program distribution medium readable by a computer or a processor. The computer program medium may be, for example but not limited to, an electric, magnetic, optical, infrared or semiconductor system, device or transmission medium. The medium may be a computer readable medium, a program storage medium, a record medium, a computer readable memory, a random access memory, an erasable programmable read-only memory, a computer readable software distribution package, a computer readable signal, a computer readable telecommunications signal, and a computer readable compressed software package.

Even though the invention has been described above with reference to an example according to the accompanying drawings, it is clear that the invention is not restricted thereto but it can be modified in several ways within the scope of the appended claims.

1. A combined equalization and decoding method in an electronic device, wherein the method is divided into an inner loop equalization process and an outer loop decoding process, the method comprising:
receiving information transmitted through a communication channel;
carrying out the inner loop equalization process to produce a first soft estimate of the transmitted information by applying known information on properties of the communication channel to the received information;
carrying out the outer loop decoding process to produce a second soft estimate of the transmitted information by applying channel code information to the first soft estimate of the transmitted information;
feeding the second soft estimate of the transmitted information back to an equalizer for production of an additional soft estimate of the transmitted information;
carrying out inner loop equalization and outer loop decoding processes for a respectively determined number of times, a total number of inner loop equalization processes being determined to be higher than a total number of outer loop decoding processes, and
outputting decoded information after the outer loop decoding process has been carried out for a last time.

2. A combined equalization and decoding method in an electronic device, wherein the method is divided into an inner loop equalization process and an outer loop decoding process, the method comprising:
receiving information transmitted through a communication channel;
carrying out the inner loop equalization process to produce a first soft estimate of the transmitted information by applying known information on properties of the communication channel to the received information;
determining, after each inner loop equalization process, based on a result of the inner loop equalization process, whether or not to carry out an additional inner loop equalization process to improve the first soft estimate;
carrying out the additional inner loop equalization process by applying known information on the properties of the communication channel to a soft estimate obtained in a previous inner loop equalization process, if it has been determined that the additional inner loop equalization process is to be carried out;
carrying out the outer loop decoding process to produce a second soft estimate of the transmitted information by applying channel code information to the first soft estimate of the transmitted information obtained as a result of a latest inner loop equalization process if it has been determined that no additional inner loop equalization process is to be carried out;
feeding the second soft estimate of the transmitted information back to an equalizer for production of an additional soft estimate of the transmitted information;
carrying out inner loop equalization and outer loop decoding processes for a respectively determined number of times, and
outputting decoded information after the outer loop decoding process has been carried out for a last time.

3. The method of claim 2, further comprising determining, based on an estimated interference variance of a result of the inner loop equalization process, whether or not to carry out the additional inner loop equalization process in order to improve the first soft estimate.

4. The method of claim 2, further comprising determining, based on a change in an estimated interference variance of a result of the inner loop equalization process with respect to a previous result of the inner loop equalization process, whether or not to carry out the additional inner loop equalization process to improve the first soft estimate.

5. The method of claim 1, further comprising:
combining the first soft estimate of the transmitted information obtained as a result of a latest inner loop equalization process with the second soft estimate of the transmitted information obtained as a result of a latest outer loop decoding process before carrying out a next inner loop equalization process, and
removing an effect of the first soft estimate of the transmitted information used in the latest outer loop decoding process from the second soft estimate of the transmitted information obtained as a result of the latest decoding process.

6. The method of claim 1, further comprising deinterleaving the first soft estimate of the transmitted information obtained as a result of the inner loop equalization process before carrying out the outer loop decoding process, and interleaving the second soft estimate of the transmitted information obtained as a result of the outer loop decoding process before carrying out the additional inner loop equalization process.

7. The method of claim 1, wherein the received information comprises received symbol values and the inner loop equalization process for received symbol values is carried to produce a soft estimate for each possibly transmitted symbol with respect to each received symbol, the method further comprising converting the soft estimates of each possibly transmitted symbol into an estimated symbol value before the additional inner loop equalization process.

8. The method of claim 1, the inner loop equalization process comprising estimating interference in the received information and removing the interference from the received information.

9. An electronic device comprising:
a reception unit configured to receive information transmitted through a communication channel;
an equalization unit configured to equalize the received information, produce a first soft estimate of the transmitted information by applying known information on properties of the communication channel to the received information, and output the first soft estimate of the transmitted information;
a decoding unit configured to produce a second soft estimate of the transmitted information by applying channel code information to the first soft estimate of the transmitted information received from the equalization unit, and feed the second soft estimate of the transmitted information back to the equalization unit for production of an additional soft estimate of the transmitted information, or output decoded information after the decoding unit has decoded the first soft estimate of the transmitted information for a last time, and
a controller configured to control processing of received information by determining, respectively, a number of times the equalization unit equalizes the received information and a number of times the decoding unit decodes the first soft estimate received from the equalization unit, a total number of equalization processes being determined to be higher than a total number of decoding processes.

10. An electronic device comprising:
a reception unit configured to receive information transmitted through a communication channel;
an equalization unit configured to equalize the received information, produce a first soft estimate of the transmitted information by applying known information on properties of the communication channel to the received information, and output the first soft estimate of the transmitted information;
a decoding unit configured to produce a second soft estimate of the transmitted information by applying channel code information to the first soft estimate of the transmitted information received from the equalization unit, and feed the second soft estimate of the transmitted information back to the equalization unit for production of an additional soft estimate of the transmitted information or output the decoded information after the decoding unit has decoded the first soft estimate of the transmitted information for a last time, and
a controller configured to determine, after each equalization process carried out by the equalization unit, based on a result of the equalization process, whether or not to carry out an additional equalization process to improve the first soft estimate before a decoding process, and feed the first soft estimate of the transmitted information back to the equalization unit for the additional equalization if the controller determines that another equalization process is to be carried out, or to the decoding unit for the decoding, if the controller determines that no other equalization process is to be carried out before the decoding process.

11. The electronic device of claim 10, wherein the controller is configured to determine whether or not to carry out an additional inner loop equalization process to improve the first soft estimate based on an estimated interference variance of the output of the equalization unit.

12. The electronic device of claim 10, wherein the controller is configured to determine whether or not to carry out an additional inner loop equalization process to improve the first soft estimate, based on a change in an estimated interference variance of the result of the equalization process carried out by the equalization unit with respect to the previous result of the inner loop equalization process carried out by the equalization unit.

13. The electronic device of claim 9, further comprising:
a combining unit configured to combine, before the next equalization carried out by the equalization unit, the first soft estimate of the transmitted information most recently outputted from the equalization unit with the second soft estimate of the transmitted information most recently outputted from the decoding unit, and
a subtracting unit configured to remove an effect of the most recent first soft estimate of the transmitted information inputted to the decoding unit from the second soft estimate of the transmitted information outputted from the decoding unit as a result of the latest decoding process.

14. The electronic device of claim 9, further comprising:
a deinterleaver configured to deinterleave the first soft estimate of the transmitted information outputted from the equalization unit, and output the deinterleaved soft estimate of the transmitted information to the decoding unit if the controller determines that a decoding process is to be carried out, and
an interleaver configured to interleave the second soft estimate of the transmitted information outputted from the decoding unit after the decoding process, and output the interleaved second soft estimate of the transmitted information to the equalization unit.

15. The electronic device of claim 9, wherein the received information comprises received symbol values, and the equalization unit produces a soft estimate for each possibly transmitted symbol with respect to each received symbol, and the electronic device further comprises a symbol converter configured to convert the soft estimates of each possibly transmitted symbol into an estimated symbol value and output the estimated symbol values to the equalization unit for further equalization.

16. The electronic device of claim 9, wherein the equalization unit is configured to estimate interference in the received information, and remove the interference from the received information.

17. An electronic device comprising:
reception means for receiving information transmitted through a communication channel;
equalization means for equalizing the received information, producing a first soft estimate of the transmitted information by applying known information on properties of the communication channel to the received information, and outputting the first soft estimate of the transmitted information;
decoding means for producing a second soft estimate of the transmitted information by applying channel code information to the first soft estimate of the transmitted information received from the equalization unit, and feeding the second soft estimate of the transmitted information back to the equalization unit for production of an additional soft estimate of the transmitted information, or outputting decoded information after the decoding means have decoded the first soft estimate of the transmitted information for the last time; and
means for controlling processing of received information by determining, respectively, a number of times the equalization means equalize the received information and a number of times the decoding means decode the first soft estimate received from the equalization means, a total number of equalization processes being determined to be higher than a total number of decoding processes.

18. An electronic device comprising:
reception means for receiving information transmitted through a communication-channel;
equalization means for equalizing the received information, producing a first soft estimate of the transmitted information by applying known information on properties of the communication channel to the received information, and outputting the first soft estimate of the transmitted information;
decoding means for producing a second soft estimate of the transmitted information by applying channel code information to the first soft estimate of the transmitted information received from the equalization unit, feeding the second soft estimate of the transmitted information back to the equalization means for production of an additional soft estimate of the transmitted information or outputting decoded information after the decoding means have decoded the first soft estimate of the transmitted information for the last time, and
means for determining, after each equalization process carried out by the equalization means, based on a result of the equalization process, whether or not to carry out an additional equalization process to improve the first soft estimate before decoding process, and feed the first soft estimate of the transmitted information back to the equalization means for the additional equalization if it is determined that another equalization process is to be carried out, or to the decoding means for the decoding, if it is determined that no other equalization process is to be carried out before the decoding process.

19. A computer program distribution medium readable by a computer and encoding a computer program of instructions for executing a computer process for combined equalization and decoding in an electronic device, the process comprising:
receiving information transmitted through a communication channel;
carrying out an inner loop equalization process to produce a first soft estimate of the transmitted information by applying known information on properties of the communication channel to the received information;
carrying out an outer loop decoding process to produce a second soft estimate of the transmitted information by applying channel code information to the first soft estimate of the transmitted information;
feeding the second soft estimate of the transmitted information back to equalizer for production of an additional soft estimate of the transmitted information;
carrying out inner loop equalization and outer loop decoding processes for respectively determined number of times, the total number of inner loop equalization processes being determined to be higher than the total number of outer loop decoding processes, and
outputting decoded information after the outer loop decoding process has been carried out for the last time.

20. The computer program distribution medium of claim 19, the distribution medium including at least one of the following mediums: a computer readable medium, a program storage medium, a record medium, a computer readable memory, a computer readable software distribution package, a computer readable signal, a computer readable telecommunications signal, and a computer readable compressed software package.

21. A computer program distribution medium readable by a computer and encoding a computer program of instructions for executing a computer process for combined equalization and decoding in an electronic device, the process comprising:
receiving information transmitted through a communication channel;
carrying out the inner loop equalization process to produce a first soft estimate of the transmitted information by applying known information on properties of the communication channel to the received information;
determining, after each inner loop equalization process, based on the result of the inner loop equalization process, whether or not to carry out an additional inner loop equalization process to improve the first soft estimate;
carrying out the additional inner loop equalization process by applying known information on the properties of the communication channel to the soft estimate obtained in the previous inner loop equalization process, if it has been determined that the additional inner loop equalization process is to be carried out;
carrying out the outer loop decoding process to produce a second soft estimate of the transmitted information by applying a channel code information to the first soft estimate of the transmitted information obtained as a result of the latest inner loop equalization process, if it has been determined that the additional inner loop equalization process shall not be carried out;
feeding the second soft estimate of the transmitted information back to the equalizer for production of an additional soft estimate of the transmitted information;
carrying out inner loop equalization and outer loop decoding processes for respectively determined number of times; and
outputting decoded information after the outer loop decoding process has been carried out for the last time.

22. The computer program distribution medium of claim 21, the distribution medium including at least one of the following mediums: a computer readable medium, a program storage medium, a record medium, a computer readable memory, a computer readable software distribution package, a computer readable signal, a computer readable telecommunications signal, and a computer readable compressed software package.

23. The method of claim 2, further comprising:
combining the first soft estimate of the transmitted information obtained as a result of a latest inner loop equalization process with the second soft estimate of the transmitted information obtained as a result of a latest outer loop decoding process before carrying out a next inner loop equalization process, and
removing an effect of the first soft estimate of the transmitted information used in the latest outer loop decoding process from the second soft estimate of the transmitted information obtained as a result of the latest decoding process.

24. The method of claim 2, further comprising deinterleaving the first soft estimate of the transmitted information obtained as a result of the inner loop equalization process before carrying out the outer loop decoding process, and interleaving the second soft estimate of the transmitted information obtained as a result of the outer loop decoding process before carrying out the additional inner loop equalization process.

25. The method of claim 2, wherein the received information comprises received symbol values and the inner loop equalization process for received symbol values is carried to produce a soft estimate for each possibly transmitted symbol with respect to each received symbol, the method further comprising converting the soft estimates of each possibly transmitted symbol into an estimated symbol value before the additional inner loop equalization process.

26. The method of claim 2, the inner loop equalization process comprising estimating interference in the received information and removing the interference from the received information.

27. The electronic device of claim 10, further comprising:
a combining unit configured to combine, before the next equalization carried out by the equalization unit, the first soft estimate of the transmitted information most recently outputted from the equalization unit with the second soft estimate of the transmitted information most recently outputted from the decoding unit, and
a subtracting unit configured to remove an effect of the most recent first soft estimate of the transmitted information inputted to the decoding unit from the second soft estimate of the transmitted information outputted from the decoding unit as a result of the latest decoding process.

28. The electronic device of claim 10, further comprising:
a deinterleaver configured to deinterleave the first soft estimate of the transmitted information outputted from the equalization unit, and output the deinterleaved soft estimate of the transmitted information to the decoding unit if the controller determines that a decoding process is to be carried out, and
an interleaver configured to interleave the second soft estimate of the transmitted information outputted from the decoding unit after the decoding process, and output the interleaved second soft estimate of the transmitted information to the equalization unit.

29. The electronic device of claim 10, wherein the received information comprises received symbol values, and the equalization unit produces a soft estimate for each possibly transmitted symbol with respect to each received symbol, and the electronic device further comprises a symbol converter configured to convert the soft estimates of each possibly transmitted symbol into an estimated symbol value and output the estimated symbol values to the equalization unit for further equalization.

30. The electronic device of claim 10, wherein the equalization unit is configured to estimate interference in the received information, and remove the interference from the received information.
